(19) United States
(12) Patent Application Publication
(10) Pub. No.: US 2026/0088262 A1
(43) Pub. Date: Mar. 26, 2026

(54) GAS SPRAYING APPARATUS, SUBSTRATE PROCESSING APPARATUS, AND THIN FILM DEPOSITION METHOD

(71) Applicant: JUSUNG ENGINEERING CO., LTD., Gwangju-si, Gyeonggi-do (KR)

(72) Inventors: Won Tae CHO, Gwangju-Si, Gyeonggi-Do (KR); Chul Joo HWANG, Gwangju-Si, Gyeonggi-Do (KR)

(21) Appl. No.: 19/109,677

(22) PCT Filed: Sep. 7, 2023
(86) PCT No.: PCT/KR2023/013390

§ 371 Date: Mar. 7, 2025

(30) Foreign Application Priority Data
Sep. 8, 2022 (KR) 10-2022-0114532
Jun. 23, 2023 (KR) 10-2023-0081366

(51) Int. Cl. H01J 37/32; C23C 16/455; C23C 16/458; C23C 16/507

(52) U.S. Cl. CPC H01J 37/32541; C23C 16/45536; C23C 16/45544; C23C 16/45561; C23C 16/4583; C23C 16/507; H01J 37/3244; H01J 2237/332; H10P 14/3434; H10P 14/69215; H10P 14/69433

(57) ABSTRACT

The present disclosure relates to an apparatus for injecting a gas, an apparatus for processing a substrate, and a method for depositing a thin-film, and more specifically, to an apparatus for injecting a gas to deposit a thin-film by injecting a gas to a substrate, an apparatus for processing a substrate, and a method for depositing a thin-film. An apparatus for injecting a gas in accordance with an exemplary embodiment includes: a first electrode in which a first gas supply path and a second gas supply path are separately defined and which has first and second gas supply holes connected to the first and second gas supply paths, respectively; and a second electrode which is electrically insulated from and spaced apart from the first electrode and has a plurality of openings arranged alternately with the first and second supply holes.

### TECHNICAL FIELD

The present disclosure relates to an apparatus for injecting a gas, an apparatus for processing a substrate, and a method for depositing a thin-film, and more specifically, to an apparatus for injecting a gas to deposit a thin-film by injecting a gas to a substrate, an apparatus for processing a substrate, and a method for depositing a thin-film.

### BACKGROUND ART

In general, a semiconductor element or a display device is manufactured by depositing various materials in the form of thin-films on a substrate and patterning the deposited thin-films. To this end, various different processes such as a deposition process, an etching process, a cleaning process, and a drying process are performed.

Here, the deposition process forms, on a substrate, a thin-film having a property required for a semiconductor element or a display device. The above-described deposition process is generally performed by a substrate processing apparatus that injects a process gas by using a gas injecting apparatus having a plurality of injecting holes to form the thin-film on the substrate through a chemical reaction.

When the thin-film is formed on the substrate by using the gas injecting apparatus having the plurality of injecting holes, securing of deposition uniformity is extremely important. Thus, a demand for the gas injecting apparatus having an improved opening structure to deposit a uniform thin-film is continuously increasing.

### Related Art Document

[Korea Patent document] KR 10-2004-0104197 A

### DISCLOSURE OF THE INVENTION

### Technical Problem

The present disclosure provides an apparatus for injecting a gas, which is capable of depositing a uniform thin-film, an apparatus for processing a substrate, and a method for depositing a thin-film.

### Technical Solution

In accordance with an exemplary embodiment, an apparatus for injecting a gas includes: a first electrode in which a first gas supply path and a second gas supply path are separately defined and which has first and second gas supply holes connected to the first and second gas supply paths, respectively; and a second electrode which is electrically insulated from and spaced apart from the first electrode and has a plurality of openings arranged alternately with the first and second supply holes.

The second electrode may be spaced apart from the first electrode by a distance greater than 3 mm and equal to or less than 25 mm.

The opening may include: a first opening defined at a first electrode side; and a second opening connected to the first opening and having a diameter greater than that of the first opening.

The first opening may have a diameter of 1 mm to 3 mm.

The second opening may have a diameter of 10 mm to 14 mm.

The opening may further include a third opening defined between the first opening and the second opening to connect the first opening and the second opening.

The third opening may have a cross-section that gradually increases in a direction toward the second opening.

The second opening may have a diameter of 25 mm to 75 mm.

The second opening may have a thickness of 35 mm to 100 mm.

The openings may be arranged with a distance of 12 mm to 20 mm.

The first opening and the second opening may have different lengths from each other.

The first opening may have a length greater than that of the second opening.

The second opening may have a length greater than that of the first opening.

In accordance with another exemplary embodiment, an apparatus for processing a substrate includes: a chamber; a substrate support apparatus disposed in the chamber to support a substrate loaded into the chamber; the apparatus for injecting the gas, which is disposed in the chamber to inject the gas toward the substrate support apparatus; and a power supply apparatus connected to the apparatus for injecting the gas to supply power to the apparatus for injecting the gas.

The power supply apparatus may be connected to the second electrode to supply power to the second electrode.

The power supply apparatus may supply power to the first electrode and the second electrode.

In accordance with yet another exemplary embodiment, a method for depositing a thin-film by using the above-described apparatus for processing the substrate deposits a thin-film on a substrate by supplying a first gas through the first gas supply path and a second gas through the second gas supply path.

The thin-film may be deposited on the substrate by generating plasma between the first electrode and the second electrode and generating plasma in the second electrode.

The thin-film may be deposited on the substrate by generating plasma between the second electrode and the substrate support apparatus.

The thin-film may be deposited on the substrate by supplying at least one of the first gas and the second gas and using a chemical vapor deposition (CVD) method or an atomic layer deposition (ALD) method.

The thin-film may include at least one of an IZO thin-film in which indium (In) is doped into zinc oxide (ZnO), a GZO thin-film in which gallium (Ga) is doped into zinc oxide (ZnO), an IGZO thin-film in which indium (In) and gallium (Ga) are doped into zinc oxide (ZnO), a thin-film having a high dielectric constant (High-K), a silicon oxide (SiO₂) thin-film, and a silicon nitride (SiN) thin-film.

### Advantageous Effects

According to the exemplary embodiment, the deposition uniformity may be improved by minimizing the distance between the openings through which a process gas is injected.

Also, the high-density plasma may be formed, and thus the high-quality thin-film may be formed.

### BRIEF DESCRIPTION OF THE DRAWINGS

FIG. 1 is a schematic view illustrating an apparatus for processing a substrate in accordance with an exemplary embodiment;

FIG. 2 is a view illustrating an arrangement structure of openings in an apparatus for injecting a gas in accordance with an exemplary embodiment; and

FIG. 3 is a view illustrating a state in which supply holes and openings are defined in the apparatus for injecting the gas in accordance with an exemplary embodiment.

### MODE FOR CARRYING OUT THE INVENTION

Hereinafter, specific embodiments will be described in detail with reference to the accompanying drawings. The present invention may, however, be embodied in different forms and should not be construed as limited to the embodiments set forth herein. Rather, these embodiments are provided so that the present invention will be thorough and complete, and will fully convey the scope of the present invention to those skilled in the art.

It will also be understood that when a layer, a film, a region or a plate is referred to as being ‘on’ another one, it can be directly on the other one, or one or more intervening layers, films, regions or plates may also be present.

Also, spatially relative terms, such as “above” or “upper” and “below” or “lower” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. In the drawings, the thicknesses of layers and regions are exaggerated for clarity. In the figures, like reference numerals refer to like elements throughout.

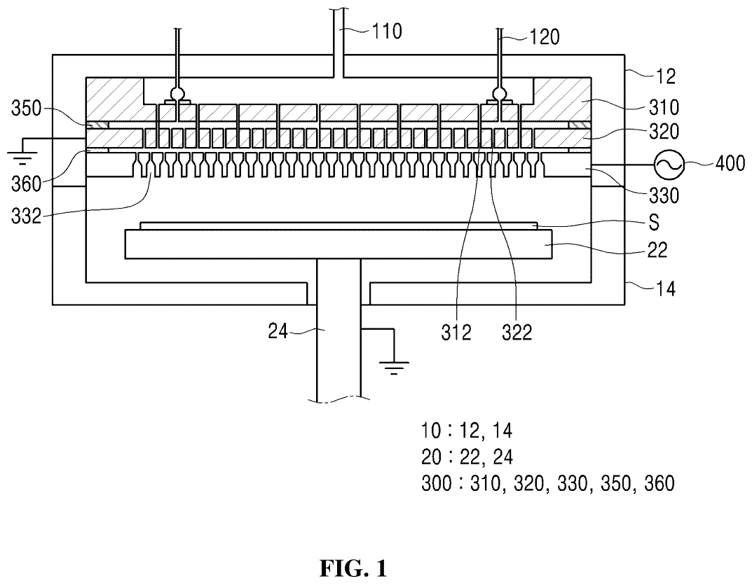

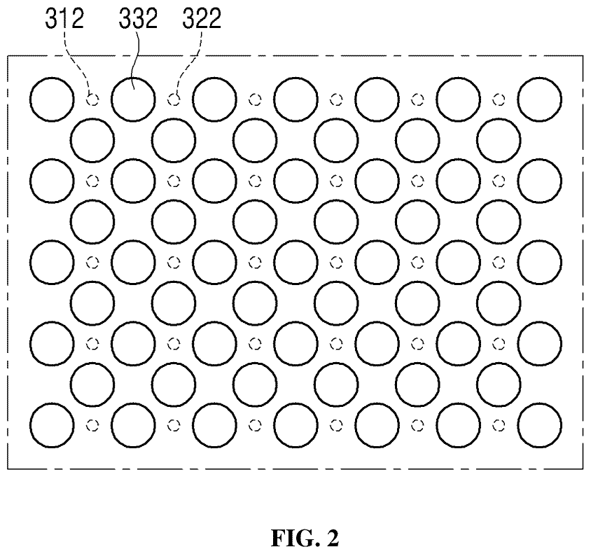

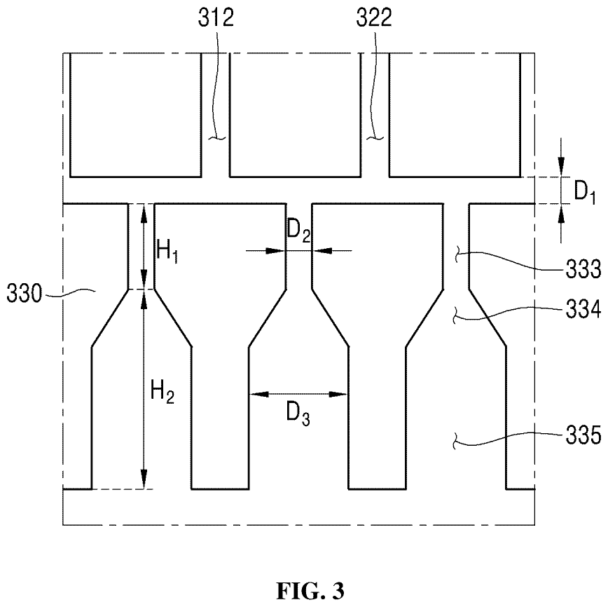

FIG. 1 is a schematic view illustrating an apparatus for processing a substrate (hereinafter, referred to as a substrate processing apparatus) in accordance with an exemplary embodiment. Also, FIG. 2 is a view illustrating an arrangement structure of openings in an apparatus for injecting a gas (hereinafter, referred to as a gas injecting apparatus) in accordance with an exemplary embodiment, and FIG. 3 is a view illustrating a state in which supply holes and openings are formed in the gas injecting apparatus in accordance with an exemplary embodiment.

Referring to FIGS. 1 to 3, the substrate processing apparatus in accordance with an exemplary embodiment includes: a chamber 10; a substrate support apparatus 20 installed in the chamber 10 to support a substrate S provided in the chamber 10; a gas injecting apparatus 300 installed in the chamber 10 to inject a gas to the substrate support apparatus 20; and a power supply apparatus 400 connected to the gas injecting apparatus 300 to supply power for generating plasma in the chamber 10 to the gas injecting apparatus 300. Also, the substrate processing apparatus may further include a control device (not shown) for controlling the power supply apparatus 400.

The chamber 10 has a predetermined reaction space and seals the space. The chamber 10 may include a body 14 having a predetermined reaction space by including an approximately circular or rectangular flat part and a sidewall part extending upward from the flat part and a lid 12 disposed on the approximately circular or rectangular body 14 to seal the reaction space. However, the exemplary embodiment is not limited to the shape of the chamber 10. For example, the chamber 10 may be manufactured into various shapes in correspondence to a shape of a substrate S.

An exhaust hole (not shown) may be formed in a predetermined area of a bottom surface of the chamber 10, and an exhaust pipe (not shown) connected to the exhaust hole may be disposed outside the chamber 10. Also, an exhaust pipe may be connected to an exhaust device (not shown). A vacuum pump such as a turbo-molecular pump may be used as the exhaust device. Thus, the inside of the chamber 10 may be vacuum-suctioned by the exhaust device to a predetermined reduced-pressure atmosphere, e.g., a predetermined pressure of 0.1mTorr or less. The exhaust pipe may be installed not only on a bottom surface of the chamber 10 but also on a side surface of the chamber 10 below the substrate support apparatus 20 that will be described later. Also, a plurality of exhaust pipes and exhaust devices connected thereto may be further installed to reduce a time for exhausting.

Also, the substrate S loaded into the chamber 10 for a substrate processing process, e.g., a thin-film depositing process, may be seated on the substrate support apparatus 20. The substrate support apparatus 20 may include, e.g., an electrostatic chuck to suction the substrate S by electrostatic force so that the substrate S is seated and supported or support the substrate S by vacuum-suctioning or mechanical force.

The substrate support apparatus 20 may have a shape corresponding to that of the substrate S, e.g., a circular or rectangular shape. The substrate support apparatus 20 may include a substrate support 22 on which the substrate S is seated and a lift 24 disposed below the substrate support 22 to move the substrate support 22 vertically. Here, the substrate support 22 may be manufactured larger than the substrate S, and the lift 24 may support at least one area, e.g., a central portion, of the substrate support 22 and move the substrate support 22 toward the gas injecting apparatus 300 when the substrate S is seated on the substrate support 22. Also, a heater (not shown) may be installed in the substrate support 22. The heater generates heat at a predetermined temperature to heat the substrate support 22 and the substrate S placed on the substrate support 22, so that a thin-film is deposited uniformly on the substrate S.

A gas supply apparatus may be installed on the lid 12 of the chamber 10. The gas supply apparatus may pass through the lid 12 of the chamber 10 and include a first gas supply unit 110 and a second gas supply unit 120 to provide each of a first gas and a second gas to the gas injecting apparatus 300. Here, the first gas may include a source gas, and the second gas may include a reaction gas. However, the exemplary embodiment is not limited thereto. For example, the first gas may include the reaction gas, the second gas may include the source gas, or at least one of the first gas and the second gas may include a mixed gas in which the source gas and the reaction gas are mixed. Alternatively, at least one of the first gas and the second gas may be a purge gas. That is, each of the first gas supply unit 110 and the second gas supply unit 120 does not necessarily provide only one gas. Each of the first gas supply unit 110 and the second gas supply unit 120 may simultaneously supply a plurality of gases or supply a selected gas among the plurality of gases.

The gas injecting apparatus 300 is installed inside the chamber 10, e.g., a bottom surface of the lid 12, and a first gas supply path for injecting and supplying the first gas onto the substrate and a second gas supply path for injecting and supplying the second gas onto the substrate are formed in the gas injecting apparatus 300. Since the first gas supply path and the second gas supply path are independent and separated from each other, the first gas and the second gas may be separately supplied onto the substrate instead of being mixed in the gas injecting apparatus 300.

More specifically, the gas injecting apparatus 300, in which the first gas supply path and the second gas supply path are separated from each other, includes a first electrode having a first gas supply hole 312 and a second gas supply hole 314 connected to the first gas supply path and the second gas supply path, respectively, and a second electrode 330 spaced apart from the first electrode and having a plurality of openings 332 arranged alternately with the first gas supply hole 312 and the second gas supply hole 314.

The first electrode may include an upper frame 310 and a lower frame 320. Here, the upper frame 310 is detachably coupled to the bottom surface of the lid 12, and at the same time, a portion of a top surface, e.g., a central portion of the top surface, of the upper frame 310 is spaced a predetermined distance from the bottom surface of the lid 12. Accordingly, the first gas supplied from the first gas supply unit 110 may be diffused in a space between the top surface of the upper frame 310 and the bottom surface of the lid 12. Also, the lower frame 320 is spaced at a predetermined distance from a bottom surface of the upper frame 310. Accordingly, the second gas supplied from the second gas supply unit 120 may be diffused in the space between a top surface of the lower frame 320 and the bottom surface of the upper frame 310. The upper frame 310 and the lower frame 320 may be connected along outer circumferential surfaces thereof and integrated with each other to define an inner spaced space, and the outer circumferential surfaces may be sealed by a first sealing member 350. Here, the first sealing member 350 may be made of an insulating material to electrically insulate the upper frame 310 and the lower frame 320 from each other or, on the contrary, a conductive material to electrically connect the upper frame 310 and the lower frame 320 to each other.

The first gas supply path may be formed so that the first gas supplied from the first gas supply unit 110 is diffused in a space between the bottom surface of the lid 12 and the upper frame 310 and supplied into the chamber 10 through the upper frame 310 and the lower frame 320. Here, the first gas supply hole 312 may be connected to the first gas supply path and pass through the upper frame 310 and the lower frame 320 to be isolated from the space between the top surface of the lower frame 320 and the bottom surface of the upper frame 310 at a lower portion of the space between the top surface of the upper frame 310 and the bottom surface of the lid 12.

Also, the second gas supply path may be formed so that the second gas supplied from the second gas supply unit 120 is diffused in a space between the bottom surface of the upper frame 310 and the top surface of the lower frame 320 and supplied into the chamber 10 through the lower frame 320. Here, the second gas supply hole 322 may be connected to the second gas supply path and pass through the lower frame 320 at a lower portion of the space between the bottom surface of the upper frame 310 and the top surface of the lower frame 320.

Accordingly, the first gas supply path and the second gas supply path may not communicate with each other, and the first gas and the second gas may be separately supplied downward from the gas supply apparatus through the first electrode.

The second electrode 330 may be insulated from the first electrode and spaced downward from the first electrode. That is, the second electrode 330 may be insulated from the lower frame 320 and spaced downward from the lower frame 320. The second electrode 330 may be spaced a predetermined distance D1 from the bottom surface of the lower frame 320. Accordingly, the first gas and the second gas supplied downward through the first electrode may be diffused in a space between a top surface of the second electrode 330 and the bottom surface of the lower frame 320. The lower frame 320 and the second electrode 330 may have a structure of sealing an outer circumferential surface of a second sealing member 360. Here, the second sealing member 360 may be made of an insulating material to electrically insulate the lower frame 320.

Here, the second electrode 330 may be spaced downward from the first electrode by a distance by which a plasma sheath region formed on a surface of the first electrode, i.e., the bottom surface of the lower frame 320, is not in overlap with a plasma sheath region formed on a surface of the second electrode, i.e., the top surface of the second electrode 330. Here, the plasma sheath region represents a dark field region in which almost no plasma is formed although energy is exchanged as positive (+) ions are concentrated between plasma and a surface of a structure.

When the plasma sheath region formed on the bottom surface of the lower frame 320 overlaps the plasma sheath region formed on the top surface of the second electrode 330, plasma is not formed between the bottom surface of the lower frame 320 and the top surface of the second electrode 330. However, in accordance with an exemplary embodiment, as the lower frame 320 and the second electrode 330 are spaced apart from each other by a distance by which the plasma sheath region formed on the bottom surface of the lower frame 320 does not overlap the plasma sheath region formed on the top surface of the second electrode 330, plasma may be generated between the bottom surface of the lower frame 320 and the top surface of the second electrode 330.

When the space between the bottom surface of the lower frame 320 and the top surface of the second electrode 330 becomes extremely wide, a gas may stagnate between the bottom surface of the lower frame 320 and the top surface of the second electrode 330, and an overall size of the gas injecting apparatus may increase. Thus, the second electrode 330 may be spaced apart from the first electrode by a distance greater than 3 mm and equal to or less than 25 mm. When the second electrode 330 is spaced apart from the first electrode by a distance of 3 mm or less, plasma may not be generated in the space between the bottom surface of the lower frame 320 and the top surface of the second electrode 330, and when the distance is greater than 25 mm, a high-quality thin film may not be deposited.

Also, the second electrode 330 has a plurality of openings 332 arranged alternately with the above-described first and second gas supply holes 312 and 322. That is, as illustrated in FIG. 2, when the first electrode and the second electrode 330 are viewed from above or below, the plurality of openings 332 do not overlap one of the first gas supply hole 312 and the second gas supply hole 322. Each of the plurality of openings 332 may be disposed between the first gas supply hole 312 along at least one direction when the first electrode and the second electrode 330 are viewed from above or below. Also, each of the plurality of openings 332 may be defined at a central position between the first gas supply hole 312 and the second gas supply hole 322 along at least one direction.

When the opening 332 is arranged to overlap the first gas supply hole 312 and the second gas supply hole 314, most of gases supplied from the first gas supply hole 312 and the second gas supply hole 314 may be injected through the opening 332 that overlaps the first gas supply hole 312 and the second gas supply hole 314. However, all of the gases may not be injected downward through the opening 332. Some gases may flow and stagnate in the space between the bottom surface of the lower frame 320 and the top surface of the second electrode 330 instead of being directly injected through the opening 332. Since the above-described stagnant gas interrupts a smooth flow of the gas and causes particle formation, in accordance with an exemplary embodiment, the plurality of openings 332 may be defined in the second electrode 330 to be alternately with each of the first gas supply hole 312 and the second gas supply hole 322

As illustrated in FIG. 3, the above-described openings 332 may include a first opening 333 formed at a first electrode side and a second opening 335 connected to the first opening 333 and having a diameter greater than that of the first opening 333. That is, each of the openings 332 may include a first opening 333 having a predetermined length H1 from the top surface of the second electrode 330 and a second opening 335 having a predetermined length H2 from the bottom surface of the second electrode 330. Here, the first opening 333 is a gas inlet, and the gas diffused in the space between the bottom surface of the lower frame 320 and the top surface of the second electrode 330 is introduced into the opening 332 through the first opening 333. On the other hand, the second opening 335 is a gas outlet, and the gas introduced into the opening 332 is injected downward from the second electrode 330 through the second opening 335. The first opening 333 may be arranged alternately with the first gas supply hole 312 and the second gas supply hole 322, and the second opening 335 may extend downward from the first opening 333 to have a diameter greater than that of the first opening 333. Also, each of the openings 332 may further include a third opening 334 connecting the first opening 333 and the second opening 335 between the first opening 333 and the second opening 335.

The first opening 333 may guide the gas diffused between the bottom surface of the lower frame 320 and the top surface of the second electrode 330 to the second opening 335 disposed therebelow. The above-described first opening 333 may have a diameter D2 that is selected to uniformly guide the gas diffused between the bottom surface of the lower frame 320 and the top surface of the second electrode 330 to each second opening 335. Here, the first opening 333 may have a diameter D2 to form the plasma sheath region therein. That is, the first opening 333 may form the plasma sheath region in which almost no plasma is formed because the plasma sheath regions formed on an inner surface of the second electrode 330 that forms the first opening 333 overlap each other. To the end, the first opening 333 may have a diameter D2 of 1 mm to 3 mm. When the first opening 333 has a diameter D2 less than 1 mm, the gas may not flow smoothly through the first opening 333, and when the first opening 333 has a diameter D2 greater 3 mm, plasma may be generated in the first opening 333 to cause clogging caused by particles. As such, the first opening 333 may be formed to have a length H1 of 10 to 25 mm from the upper surface of the second electrode 330.

The third opening 334 is disposed below the first opening 333 to smoothly transfer the gas supplied through the first opening 333 to the second opening 335. This third opening 334 may have a shape in which a cross-section increases from a lower end of the first opening 333 to an upper end of the second opening 335, and this shape may allow the gas supplied through the first opening 333 to be guided through the third opening 334 and smoothly transferred to the second opening 335 without stagnation. However, the third opening 334 is not an essential component. When the third opening 334 is omitted, the second opening 335 may be directly connected to a lower side of the first opening 333.

The second opening 335 is connected to the lower side of the first opening 333 or a lower side of the third opening 334. The second opening 335 generates plasma in a cylindrical electrode. That is, the second opening 335 provides a wide surface area to cause plasma ionization of the gas introduced into the second opening 335, thereby generating high-density plasma.

The above-described second opening 335 may have a diameter D3 of 10 mm to 14 mm. When the second opening 335 has a diameter D3 less than 10 mm, the high-density plasma may not be formed. Alternatively, when the second opening 335 has a diameter D3 greater than 14 mm, a thin-film may not be uniformly deposited due to an increased distance between the second openings 335. When the distance between the second openings 335 increases, the gas injected from each second opening 335 is concentrated at a predetermined position on the substrate S, which causes non-uniform deposition. However, when the distance between the second openings 335 is reduced, the gas injected from each second opening 335 may overlap on the substrate S to further uniformly deposit the thin-film. The second openings 335 may be arranged with a distance of 12 mm to 20 mm to deposit a uniform thin-film on the substrate S, and when the second opening 335 has a diameter D3 of 14 mm or less, the second opening 335 may be arranged with a distance of 12 mm to 20 mm to improve deposition uniformity.

Also, the second opening 335 may have a length H2 of 25 mm to 75 mm. That is, the second opening 335 may have the length H2 of 25 mm to 75 mm upward from the bottom surface of the second electrode 330. When the second opening 335 has the length H2 less than 25 mm, the plasma may be formed with insufficient density. On the other hands, when the second opening 335 has the length H2 greater than 75 mm, ions generated in the second opening 335 collide with the inner surface of the second electrode 330 that forms the second opening 335 to generate a hole damage due to sputtering. Thus, the second opening 335 may have the length H2 of 25 mm to 75 mm.

As described above, the first opening 333 may have the length H1 of 10 mm to 25 mm. Also, the second opening 335 may have the length H2 of 25 mm to 75 mm. Thus, the second opening 330 may have a thickness of 35 mm to 100 mm. When the second opening 335 has a thickness less than 35 mm, the second electrode 330 may be deflected by own weight, and when the second opening 335 has a thickness greater than 75 mm, the second opening 335 may occupy excessive space in the chamber 10 and thus have a poor structural efficiency. Thus, the second electrode 330 may have a thickness of 35 mm to 100 mm.

On the other hands, the length H1 of the first opening 333 and the length H2 of the second opening 335 may be adjusted within a range in which the second electrode 330 has the set thickness. That is, the length H1 of the opening 333 and the length H2 of the second opening 335 may be adjusted differently or equally.

For example, the length H1 of the first opening 333 may be greater than the length H2 of the second opening 335 within the range in which the second electrode 330 has the set thickness. When the thickness of the second electrode 330 is set to 35 mm to 100 mm and the length H2 of the second opening 335 is set to 25 mm, the first opening 333 may be set to have the length H1 of 25 mm in order to increase the density of plasma.

Also, the length H1 of the first opening 333 may be less than the length H2 of the second opening 335, i.e., the length H2 of the second opening 335 may be greater than the length H1 of the first opening 333 in order to lower the density of plasma within the range in which the second electrode 330 has the set thickness. When the thickness of the second electrode 330 is set to 35 mm to 100 mm and the length H2 of the second opening 335 is set to 25 mm, the length H1 of the first opening 333 may be set to 10 mm or more and 25 mm or less in order to lower the density of plasma.

Also, the length H1 of the first opening 333 and the length H2 of the second opening 335 may be equal to each other. As described above, as the length H1 of the first opening 333 and the length H2 of the second opening 335 are adjusted differently or equally, the plasma may be adjusted to have a desired density.

The power supply apparatus 400 may be connected to the gas injecting apparatus 300 in order to supply power for generating plasma in the chamber 10 to the gas injecting apparatus. That is, the power supply apparatus 400 may supply RF power for generating the plasma in the chamber 10.

Here, the power supply apparatus 400 may be connected to the second electrode 330 to supply RF power to only the second electrode 330, and the first electrode may be grounded. Here, the first electrode and the second electrode 330 may be insulated by a second sealing member 360 made of an insulating material. As described above, when the power supply apparatus 400 supplies the RF power to the second electrode 330, and the first electrode is grounded, the first electrode and the second electrode 330 each form an electrode for generating capacitively coupled plasma (CCP). Also, as the substrate support 22 is also grounded, the CCP may be generated between the second electrode 330 and the support 22. Alternatively, the power supply apparatus 400 may also supply power to the first electrode and the second electrode 330. In this case, the power supply apparatus 400 may supply the RF power to each of the first electrode and the second electrode 330.

The above-described substrate processing apparatus in accordance with an exemplary embodiment may be used to deposit a thin-film on the substrate S by using a chemical vapor deposition (CVD) method or an atomic layer deposition (ALD) method. Here, the thin-film deposited by the CVD or ALD method may include at least one of an IZO thin-film in which indium (In) is doped into zinc oxide (ZnO), a GZO thin-film in which gallium (Ga) is doped into zinc oxide (ZnO), an IGZO thin-film in which indium (In) and gallium (Ga) are doped into zinc oxide (ZnO), a thin-film having a high dielectric constant (High-K), a silicon oxide (SiO₂) thin-film, and a silicon nitride (SiN) thin-film.

First, when the thin-film is deposited on the substrate S by using the CVD method, a source gas and a reaction gas may be supplied on the substrate(S) at the same time. Here, the first gas may include the source gas, and the second gas may include the reaction gas. However, the exemplary embodiment is not limited thereto. For example, the first gas may include the reaction gas, the second gas may include the source gas, or at least one of the first gas and the second gas may include a mixed gas in which the source gas and the reaction gas are mixed. Alternatively, at least one of the first gas and the second gas may be a purge gas. Here, the plasma may be formed in the chamber 10 by supplying the RF power to the gas injecting apparatus 300 through the power supply apparatus 400 to improve a deposition efficiency.

Also, when the thin-film is deposited on the substrate S by using the ALD method, the source gas and the reaction gas may be alternately supplied onto the substrate(S). Here, the first gas may include the source gas, and the second gas may include the reaction gas. Alternatively, the first gas may include the reaction gas, and the second gas may include the source gas. Alternatively, at least one of the first gas and the second gas may be a purge gas. Here, processes of supplying the source gas, supplying the purge gas, supplying the reaction gas, and supplying the purge gas may form one process cycle, and the process cycle may be repeated a plurality of times to deposit the thin-film on the substrate S. Here, the plasma may be formed in the chamber 10 by supplying the RF power to the gas injecting apparatus 300 through the power supply apparatus 400, and this may be performed in the process of supplying the reaction gas to improve the deposition efficiency.

As described above, when the thin-film is deposited on the substrate S by the CVD or ALD method, the plasma may be formed between the first electrode and the second electrode 330 by supplying the RF power to the gas injecting apparatus 300 through the power supply apparatus 400, and the plasma may be generated in the second electrode 330. Also, high-density CCP may be generated between the second electrode 330 and the substrate support 22.

As described above, in accordance with an exemplary embodiment, the deposition uniformity may be improved by minimizing the distance between the openings through which a process gas is injected. Also, the high-density plasma may be formed, and thus the high-quality thin-film may be formed.

Although the specific embodiments are described and illustrated by using specific terms, the terms are merely examples for clearly explaining the embodiments, and thus, it is obvious to those skilled in the art that the embodiments and technical terms can be carried out in other specific forms and changes without changing the technical idea or essential features. Therefore, it should be understood that simple modifications according to the embodiments of the present invention may belong to the technical spirit of the present invention.

1. A first electrode in which a first gas supply path and a second gas supply path are separately defined and which has first and second gas supply holes connected to the first and second gas supply paths, respectively; and
a second electrode which is electrically insulated from and spaced apart from the first electrode and has a plurality of openings arranged alternately with the first and second gas supply holes.

2. The apparatus of claim 1,
wherein the second electrode is spaced apart from the first electrode by a distance greater than 3 mm and equal to or less than 25 mm.

3. The apparatus of claim 1,
wherein the opening comprises,
a first opening defined at a first electrode side; and
a second opening connected to the first opening;
and having a diameter greater than that of the first opening.

4. The apparatus of claim 3,
wherein the first opening has a diameter of 1 mm to 3 mm.

5. The apparatus of claim 3,
wherein the second opening has a diameter of 10 mm to 14 mm.

6. The apparatus of claim 3,
wherein the opening comprises,
a third opening defined between the first opening and the second opening to connect the first opening and the second opening.

7. The apparatus of claim 6,
wherein the third opening has a cross-section that gradually increases in a direction toward the second opening.

8. The apparatus of claim 3,
wherein the second opening has a diameter of 25 mm to 75 mm.

9. The apparatus of claim 1,
wherein the second electrode has a thickness of 35 mm to 100 mm.

10. The apparatus of claim 1,
wherein the openings are arranged with a distance of 12 mm to 20 mm.

11. The apparatus of claim 3,
wherein the first opening and the second opening have different lengths from each other.

12. The apparatus of claim 11,
wherein the first opening has a length greater than that of the second opening.

13. The apparatus of claim 11,
wherein the second opening has a length greater than that of the first opening.

14. A chamber;
a substrate support apparatus disposed in the chamber to support a substrate loaded into the chamber;
the apparatus for injecting the gas of claim 1, which is disposed in the chamber to inject the gas toward the substrate support apparatus; and
a power supply apparatus connected to the apparatus for injecting the gas to supply power to the apparatus for injecting the gas.

15. The apparatus of claim 14,
wherein the power supply apparatus is connected to the second electrode to supply power to the second electrode.

16. The apparatus of claim 14,
wherein the power supply apparatus supplies power to the first electrode and the second electrode.

17. A method for depositing a thin-film by using the apparatus for processing the substrate of claim 14,
wherein the thin-film is deposited on the substrate by supplying a first gas through the first gas supply path and a second gas through the second gas supply path.

18. The method of claim 17,
wherein the thin-film is deposited on the substrate by generating plasma between the first electrode and the second electrode and plasma in the second electrode.

19. The method of claim 17,
wherein the thin-film is deposited on the substrate by generating plasma between the second electrode and the substrate support apparatus.

20. The method of claim 17,
wherein the thin-film is deposited on the substrate by supplying at least one of the first gas and the second gas and using a chemical vapor deposition (CVD) method or an atomic layer deposition (ALD) method.

21. The method of claim 17,
wherein the thin-film comprises at least one of an IZO thin-film in which indium (In) is doped into zinc oxide (ZnO), a GZO thin-film in which gallium (Ga) is doped into zinc oxide (ZnO), an IGZO thin-film in which indium (In) and gallium (Ga) are doped into zinc oxide (ZnO), a thin-film having a high dielectric constant (High-K), a silicon oxide (SiO₂) thin-film, and a silicon nitride (SiN) thin-film.
